(19) United States
(12) Patent Application Publication
(10) Pub. No.: US 2016/0141029 A1
(43) Pub. Date: May 19, 2016

(54) HEALTH DATA ASSOCIATED WITH A RESISTANCE-BASED MEMORY

(71) Applicant: SANDISK TECHNOLOGIES INC., PLANO, TX (US)

(72) Inventors: ARIEL NAVON, REVAVA (IL); IDAN ALROD, HERZLIYA (IL); ERAN SHARON, RISHON LEZION (IL); IDAN GOLDENBERG, RAMAT HASHARON (IL); ALEXANDER BAZARSKY, HOLON (IL); TZ-YI LIU, PALO ALTO, CA (US); TIANHONG YAN, SARATOGA, CA (US)

(73) Assignee: SANDISK TECHNOLOGIES INC.

(21) Appl. No.: 14/548,205

(22) Filed: Nov. 19, 2014

(51) Int. Cl. G11C 13/00; G11C 29/02; H01L 21/66; H01L 45/00; H01L 27/24; G06F 3/06; G11C 29/50

(52) U.S. Cl. CPC G11C 13/0035; G06F 3/0604; G06F 3/0659; G06F 3/0679; G11C 29/021; G11C 29/50004; G11C 13/0069; G11C 13/004; G11C 13/0023; H01L 45/16; H01L 27/2481; H01L 45/1233; H01L 22/14; G11C 2029/5004; G11C 2029/0403

(57) ABSTRACT

A method of fabricating a resistance-based memory includes initiating formation of a conductive path through a storage element of the resistance-based memory. The method further includes recording data of one or more parameters associated with the formation of the conductive path.

### FIELD OF THE DISCLOSURE

The present disclosure is generally related to health data associated with a resistance-based memory.

### BACKGROUND

Non-volatile data storage devices, such as embedded memory devices (e.g., embedded MultiMedia Card (eMMC) devices) and removable memory devices (e.g., removable universal serial bus (USB) flash memory devices and other removable storage cards), have allowed for increased portability of data and software applications. Users of non-volatile data storage devices increasingly rely on the non-volatile storage devices to store and provide rapid access to a large amount of data.

During an operational life of a memory of a data storage device, a storage element of memory experiences wear and a storage capacity (e.g., a reliability) of the storage elements degrade. Accordingly, the data storage device may track one or more metrics corresponding to an amount of use during the operational life of the memory. Based on the one or more metrics, such as a number of program/erase cycles, the data storage device may determine a “health” of one or more regions of the memory. Improvements in tracking the health of the memory regions can enable enhanced data management at the data storage device and extend a useful life of the data storage device.

### SUMMARY

Techniques are disclosed for acquiring data associated with formation of a conductive path in a storage region of a memory, such as a storage element, a block, a die, etc. of a resistance-based memory. The data recorded during formation may be used during operation of the memory to determine reliability data that indicates a “health” of a region of the memory. For example, data associated with a number or intensity of voltage pulses, an amount of current, and/or a resistance during formation may be compared to one or more expected characteristics. When the data deviates from the one or more expected characteristics, such as when a detected resistance is outside of an expected range, a non-conforming region of the memory may be identified. The reliability data corresponding to the region may be stored at the memory or at another memory that is accessible to a data storage device that includes the memory. The data storage device may use the reliability data during an operational life of the memory as a factor in scheduling and/or performing memory operations, such as storage location selection, wear-leveling, read operations, write operations, and/or other operations associated with the memory, as illustrative, non-limiting examples.

By gathering the data that is recorded during formation of one or more conductive channels, one or more regions of the memory may be identified as “problematic” (e.g., “unhealthy” or potentially faulty) prior to the memory being used as part of the data storage device. Accordingly, the data storage device may use the reliability data to determine a health of one or more regions of the memory and/or to make decisions regarding operations to be performed at the memory based on factors that are not measureable by an amount of use of the memory. By considering the reliability data based on the information recorded during formation of a conductive channel of the memory, the data storage device may improve use of the memory to reduce power consumption, shorten program and erase times, increase data retention, increase reliability, and/or increase that operating life of the memory.

### BRIEF DESCRIPTION OF THE DRAWINGS

FIG. 1 is a block diagram of a particular illustrative embodiment of a system to form a conductive path in a memory and to record data corresponding to the conductive path;

FIG. 2 is a block diagram of a particular illustrative embodiment of a system including a data storage device that includes a memory storing data corresponding to a conductive path of the memory;

FIG. 3 is a block diagram of a particular embodiment of a memory;

FIG. 4 is a flow diagram of an embodiment of a method of fabricating a memory including recording data associated with formation of a conductive path; and

FIG. 5 is a flow diagram of an embodiment of a method of operating a data storage device using a health indicator based on a characteristic of a conductive path of a memory.

### DETAILED DESCRIPTION

Particular embodiments of the present disclosure are described with reference to the drawings. In the description, common features are designated by common reference numbers throughout the drawings.

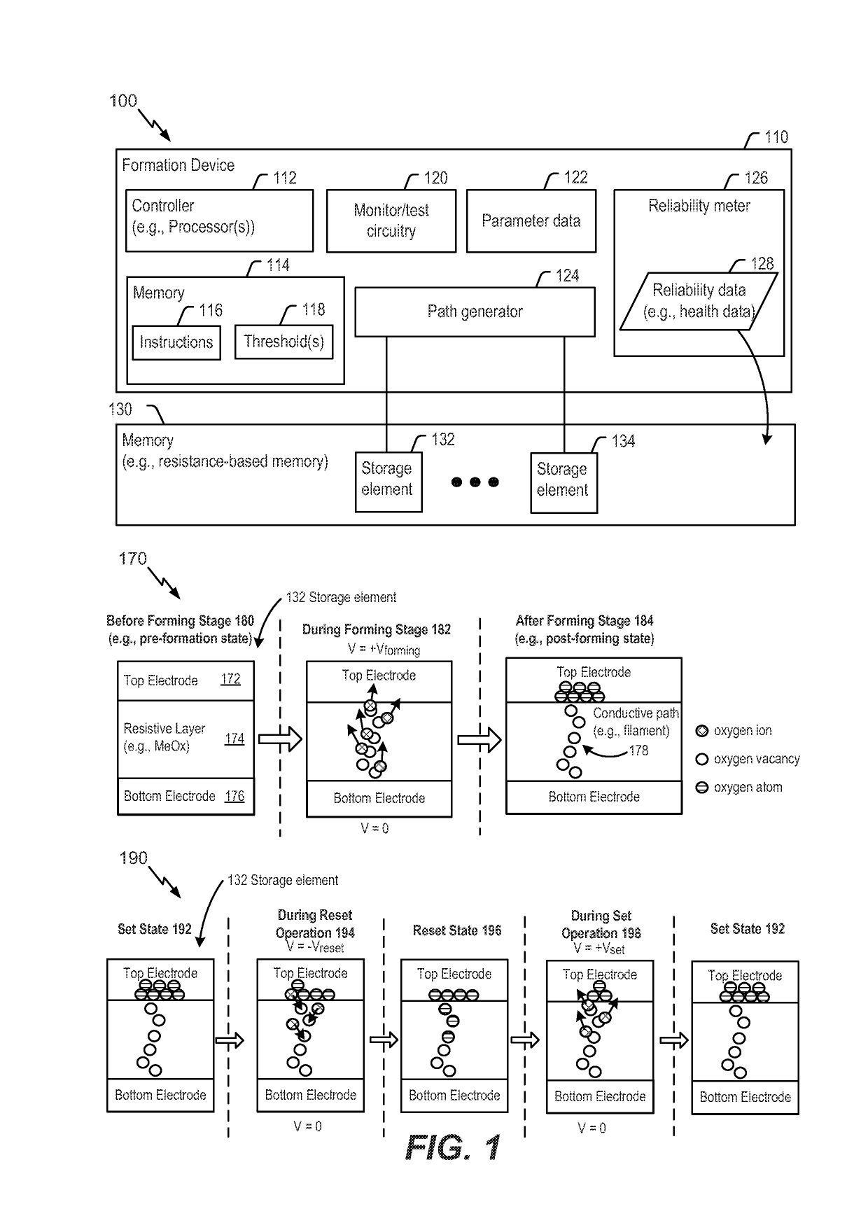

FIG. 1 is a block diagram of a particular illustrative embodiment of a system configured to form a conductive path in a memory is disclosed and generally designated 100. The system 100 includes a formation device 110 that is configured to perform one or more processing stages associated with formation of a conductive path of storage element of a memory 130, such as a resistance-based memory, and recordation of data corresponding to the conductive path.

For example, the formation device 110 may be configured to initiate formation of a conductive path through a storage element, such as a storage element 132 or a storage element 134, of the memory 130. The formation device 110 may record data, such as values of one or more parameters associated with the formation of the conductive path. The formation device 110 may be configured to identify at least one parameter of the one or more parameters that fails to satisfy a target threshold or is outside of a target range. Reliability data 128 corresponding to the storage element may be generated in response to the at least one parameter failing to satisfy the target threshold or being outside of the target range. For example, the reliability data 128 may indicate a health of the storage element, such as a particular status of multiple health statuses (e.g., a status of “healthy”, “unhealthy”, faulty, or another status, as illustrative, non-limiting examples). As used herein, “health” is used to indicate an amount and/or a type of use or wear of a system or a device, such as a memory and/or components thereof. The health of a system or a device may provide an indication and/or a prediction of an endurance of the system or the device and may be representative of an amount of wear or a decrease in (e.g., a degradation of) a storage capability of the system or the device. In some implementations, the reliability data 128 may include the recorded data. The reliability data 128 generated by the formation device 110 may be stored at the memory 130 or at another memory that is accessible to a data storage device that includes the memory 130.

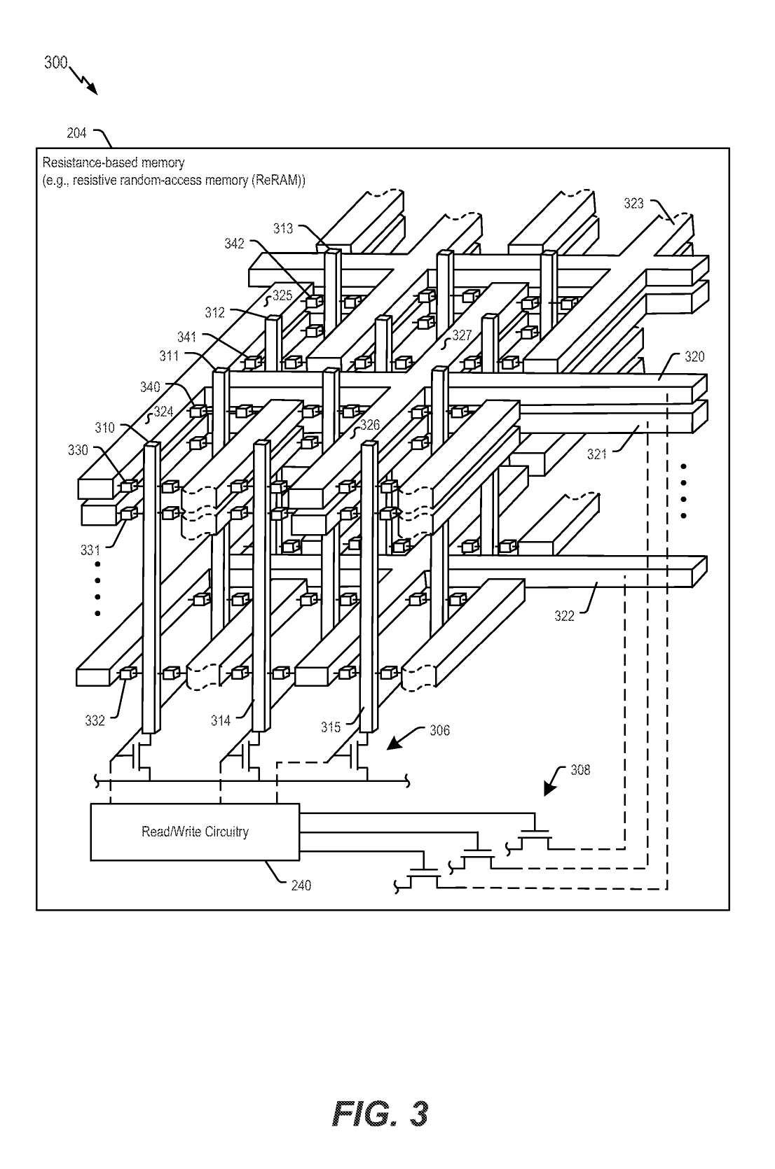

The formation device 110 may be configured to be coupled to the memory 130 prior to conductive paths being formed in storage elements of the memory 130. The memory 130 may include or correspond to a resistance-based memory, such as a resistive random access memory (ReRAM), as described further with reference to FIG. 3. The memory 130 may include an array of storage elements, such as an array of resistance-based storage elements. For example, the memory 130 may include the storage elements 132, 134. Although the memory 130 is illustrated as including two storage elements, in other implementations, the memory 130 may include fewer than two storage elements or more than two storage elements. The memory 130 may be a volatile memory or a non-volatile memory. In some implementations, the memory 130 may have a three-dimensional (3D) memory configuration. Alternatively, the memory 130 may have another configuration, such as a two-dimensional (2D) memory configuration.

The formation device 110 may include a controller 112, a memory 114, monitor/test circuitry 120, parameter data 122, a path generator 124, and a reliability meter 126. The controller 112 may include one or more processors and may be coupled to the memory 114. The controller 112 may be configured to control one or more operations of the formation device 110, such as functions performed by one or more components of the formation device 110. For example, the controller 112 may send data and/or commands to one or more components of the formation device 110, may receive data and/or commands from one or more components of the formation device 110, or a combination thereof.

The memory 114 may be a volatile memory or a non-volatile memory and may be configured to store one or more instructions 116 executable by the controller 112. The memory 114 may further be configured to store data, such as one or more thresholds 118. The one or more thresholds 118 may include one or more threshold values and/or one or more threshold ranges. The one or more threshold values may correspond to expected and/or target parameter values corresponding to formation of a conductive path at the memory 130.

The path generator 124 may include distinct path generators and may be configured to be coupled to one or more storage elements of the memory 130. The path generator 124 may be configured to cause formation of a conductive path through a storage element of the memory 130. For example, the path generator 124 may be a voltage pulse generator that is configured to generate one or more voltage pulses to be provided to a storage element to form a conductive path. In some implementations, when the path generator 124 applies multiple voltage pulses including a first voltage pulse and a second voltage pulse, the first voltage pulse and the second voltage pulse may each have the same voltage level and the same duration. In other implementations, a first voltage level and/or a first duration of the first voltage pulse may be different than a second voltage level and/or a second duration of the second voltage pulse. As another example, the path generator 124 may be a current pulse generator that is configured to generate one or more current pulses to be provided to a storage element to form a conductive path.

In some implementations, the path generator 124 may be configured to concurrently form conductive paths in multiple storage elements. For example, the path generator 124 may be configured to initiate formation of (e.g., to form) a first conductive path through the storage element 132 and, in parallel, to initiate formation of (e.g., to form) a second conductive path through the storage element 134. The first conductive path may be formed based on a first number of voltage pulses applied to the storage element 132 that is the same as or different than a second number of voltage pulses applied to the storage element 134.

An illustrative example 170 of formation of a conductive channel through the storage element 132 depicts the storage element 132 prior to a forming stage to form a conductive path 178, during the forming stage, and after the forming stage. The conductive path 178 may be formed by initializing the storage element 132 to change a state of the storage element 132 from a first state (e.g., a pre-formation state) to a second state (e.g., a post-formation state), as described herein.

Prior to the forming stage, the storage element 132 includes a top electrode 172, a resistive layer 174, and a bottom electrode 176, as depicted in a “before forming” stage 180. It is noted that the designations of “top” and “bottom” with reference to the electrodes 172, 176 are used for ease of describing the example 170 and that any other orientation of the storage element 132 may be used.

Prior to the forming stage, the storage element may be in the first state corresponding to a first resistance, such as a very high resistance state as compared to the second state, after formation of the conductive path 178. The electrodes 172, 176 may be coupled to a corresponding bit line or a wordline of the memory 130. The electrodes 172, 176 may include a conductive material. The resistive layer 174 may include a resistive material, such as a metal oxide (MeOx).

In a forming stage 182, one or more voltage pulses may be applied by the path generator 124 to the storage element 132. Applying the one or more voltage pulses may include applying a first voltage potential (V=0) to the bottom electrode 176 and applying a second voltage potential (V=+V_{forming}) to the top electrode 172. As the one or more voltage pulses are applied, oxygen ions of the resistive layer 174 may migrate toward the top electrode 172, thereby leaving oxygen vacancies within the resistive layer 174. In some implementations, a value of +Vforming increases with each pulse applied of the one or more voltage pulses. In other implementations, the one or more voltage pulses may include a single pulse where the value of +Vforming increases over time (e.g., the voltage level applied to the resistive layer 174 gradually increases without pulsing).

The one or more voltage pulses may be applied until a transition of the storage element 132 from the first state to a second state (e.g., a set state or a reset state occurs). For example, the monitor/test circuitry 120 may monitor a voltage value applied to the storage element 132, a resistance of the storage element 132, an amount of current and/or an amount of power corresponding to the storage element 132 during application of the one or more voltage pulses to determine whether the storage element 132 is in the first state or a second state. To illustrate, the transition of the storage element 132 from the first state to the second state may be determined based on the amount of current and/or the amount of power exceeding a threshold value that is indicative of formation of a conductive path. The second state may include a data storage state of the storage element 132, such as a “set” state or a “reset” state. The set state may correspond to a second resistance, such as a “low” resistance state, and the reset state may correspond to a third resistance, such as a “high” resistance state.

In an “after forming” state 184 after the forming stage 182 (e.g., after the transition and after the one or more voltage pulses are no longer applied), the storage element 132 may include oxygen atoms in the top electrode 172 and the conductive path 178 through the storage element 132. The conductive path 178 may be associated with oxygen vacancies of the resistive layer 174 between the bottom electrode 176 and the top electrode 172. The conductive path 178 through the storage element 132 may correspond to a filament of the storage element 132. Although the storage element 132 is illustrated as having no oxygen ions in the resistive layer 174 that fill the oxygen vacancies, after the forming stage, one or more oxygen ions may fill oxygen vacancies corresponding to the conductive path 178.

Although the resistive layer 174 is depicted as a single layer positioned between the top electrode 172 and the bottom electrode 176, in other implementations the resistive layer 174 may include multiple resistive layers. In some implementations, the multiple resistive layers may be stacked one on top of another with no intervening layers. In other implementations, the multiple resistive layers may be stacked with one or more intervening layers (e.g., one or more scattering layers and/or one or more coupling electrode layers), such that an intervening layer is positioned between a first resistive layer and a second resistive layer.

An illustrative example 190 of operation of the storage element 132 after formation of the conductive path 178 depicts the storage element 132 being programed from a set state 192 to a reset state 196 and programmed from the reset state 196 to the set state 192. Referring to the left depiction of the storage element 132 of the example 190, the storage element 132 is in the set state 192 (e.g., the second resistance, such as a low resistance state). Although the set state 192 is illustrated as having no oxygen ions filling the oxygen vacancies of the conductive path 178, in other implementations some oxygen vacancies may be filled with oxygen ions when the storage element 132 is in the set state 192.

During a reset operation 194, a voltage potential (V=0) may be applied to the bottom electrode 176 and a voltage potential (V=−Vᵣₑₛₑₜ) may be applied to the top electrode 172. Based on the voltages applied to the electrodes 172, 176 during the reset operation 194, oxygen ions may migrate back to the resistive layer 174 and combine with oxygen vacancies to program the storage element 132 in the reset state 196 (e.g., the third resistance, such as a high resistance state). Accordingly, the reset state 196 may have more oxygen vacancies filled with oxygen ions than the set state 192 and the storage element 132 in the reset state 196 may have a higher resistance than the storage element 132 in the set state 192.

From the reset state 196, a set operation 198 may be performed to program the storage element 132 to the set state 192. During the set operation 198, a voltage potential (V=0) may be applied to the bottom electrode 176 and a voltage potential (V=+Vₛₑₜ) may be applied to the top electrode 172. Based on the voltages applied to the electrodes 172, 176 during the set operation 198, oxygen ions may migrate from the conductive path 178 to the top electrode 172.

In some implementations, the reset state 196 may correspond to a first data value and the set state 192 may correspond to a second data value. For example, the first data value may correspond to a logical “1” or a logical “0” and the second data value may correspond to the other of the logical “1” or the logical “0”. Although the example 190 depicts applying a negative voltage during the reset operation 194 and a positive voltage for the set operation 198, in other implementations voltages of the same polarity (e.g., both positive or both negative) may be applied during the reset operation 194 and the set operation 198. Alternatively, or in addition, although the example 190 depicts applying a reset voltage (−Vᵣₑₛₑₜ) and a set voltage (+Vₛₑₜ), in other implementations a reset current may be applied to program the storage element 132 to the reset state 196 and a set current may be applied to program the storage element 132 to the set state 192.

The monitor/test circuitry 120 may be configured to generate the parameter data 122 based on monitoring the memory 130 during formation of one or more conductive paths and/or based on testing the memory 130 after formation of the one or more conductive path. For example, the monitor/test circuitry 120 may monitor and/or test one or more parameters associated with formation of a particular conductive path at the memory 130, as described further herein. The one or more parameters may include a first parameter associated with a resistance of the storage element that indicates successful formation of the conductive path, a second parameter associated with a first amount of current through a region (e.g., a storage element, a finger, a wordline, a bit line, etc.) of the resistance-based memory that includes the storage element based on a first test voltage applied to the region after formation of the conductive path, a third parameter associated with a first amount of leakage current through a neighbor storage element of the storage element based on a second test voltage applied to the storage element after formation of the conductive path, or a combination thereof, as illustrative, non-limiting examples. Additionally or alternatively, the one or more parameters may include a fourth parameter associated with a second amount of leakage current through the storage element based on a third test voltage applied to a neighbor storage element of the storage element after the formation of the conductive path, a fifth parameter associated with a number of voltage pulses applied to the storage element to form the conductive path, a sixth parameter associated with an intensity of the voltage pulses, or a combination thereof, as illustrative, non-limiting examples. Additionally or alternatively, the one or more parameters may include a seventh parameter associated with a second amount of current through the storage element during formation of the conductive path, an eighth parameter associated with a second amount of leakage current through the neighbor storage element during formation of the conductive element, or a combination thereof, as illustrative, non-limiting examples.

During formation of a particular conductive path at a particular storage element of the memory 130, the monitor/test circuitry 120 may monitor a voltage value applied to the particular storage element, a resistance of the particular storage element, an amount of current through the particular storage element during formation, a number of voltage pulses applied to the particular storage element, a total duration of one or more voltage pulses applied to the particular storage element, an amount of power applied to the particular storage element, or a combination thereof, as illustrative, non-limiting examples. Alternatively, or in addition, the monitor/test circuitry 120 may determine an intensity value associated with the one or more voltage pulses applied to the particular storage element to form the particular conductive path. The intensity value may be based on a total duration of the one or more voltage pulses applied to the particular storage element to form the particular conductive path, an amount of voltage applied to the particular storage element to form the particular conductive path, a number of the one or more voltage pulses applied to the particular storage element to form the particular conductive path, a total amount of power delivered to the particular storage element to form the particular conductive path, or a combination thereof, as illustrative, non-limiting examples.

The monitor/test circuitry 120 may test the particular storage element after an attempt to form the particular conductive path. For example, the monitor/test circuitry 120 may determine whether the particular storage element is in a pre-forming state based on a resistance of the particular storage element and may indicate that the formation of the particular conductive path is unsuccessful if the particular storage element is in the pre-forming state after the attempt. Alternatively, or in addition, the monitor/test circuitry 120 may apply a first test voltage to the storage element to identify (e.g., measure) a current flow through the storage element after the path generator 124 attempts formation of the current path. As another example, the monitor/test circuitry 120 may apply a second test voltage to a neighbor storage element of the storage element and determine an amount of leakage current through the storage element. As another example, the monitor/test circuitry 120 may perform one or more read operations on the storage element to determine an amount of read current. When multiple read operations are performed at the particular storage element, the amount of read current may be determined as an average amount of read current based on the multiple read operations. In some implementations, the monitor/test circuitry 120 may program a test data (e.g., a test pattern of data or random data) to a region of the memory that includes the storage element and then read the programmed data from the region to determine a bit-error-rate (BER) associated with the region (e.g., the storage element). Prior to initiating one or more tests, the monitor/test circuitry 120 may program the storage element to the set state or the reset state.

The reliability meter 126 may be configured to generate reliability data 128 associated with one or more storage elements of the memory 130. The reliability data 128 may include the parameter data 122, health data, or a combination thereof. For example, the reliability data 128 may include the health data and may indicate a status (e.g., a health status) associated with a storage element. The status may be determined from a set of multiple statuses, such as a set that includes statuses of “healthy”, “unhealthy”, “faulty”, and/or one or more other statuses, as illustrative, non-limiting examples. As used herein, a status of unhealthy (e.g., an unhealthy status) may refer generally to one or more statuses of the multiple health statuses and should not be unnecessarily limited to a single status. For example, the multiple health statuses may include varying degrees of unhealthy statuses.

The reliability meter 126 may indicate that a storage element has the status of faulty based on a determination that a conductive path of the particular storage element was not successfully formed (e.g., the particular storage element remains in the first state after the forming stage 182). Alternatively, or in addition, to generate reliability data corresponding to a storage element of the memory 130, the reliability meter 126 may identify at least one parameter of the one or more parameters that fails to satisfy a target threshold or that is outside of a target range. For example, the reliability meter 126 may compare the parameter data 122 to the one or more thresholds 118. To illustrate, the reliability meter 126 may select a parameter, such as an amount of leakage current associated with the storage element, a number of voltage pulses applied to form a current path of the storage element, or an intensity value associated with formation of the current path, and compare the parameter to a corresponding threshold or a corresponding threshold range. In response to a determination that the parameter does not satisfy the corresponding threshold or the corresponding threshold range, the reliability meter 126 may generate the reliability data 128 to indicate that the storage element has a status of unhealthy or faulty. In some implementations a first storage element that has a single parameter that fails to satisfy a corresponding threshold may be identified as healthier (e.g., less unhealthy) as compared to a second storage element with multiple parameters that each fail to satisfy corresponding thresholds. Additionally, the reliability meter 126 may generate the reliability data 128 to indicate that a storage element having one or more parameters that satisfy one or more thresholds and/or one or more threshold ranges has a healthy status.

In some implementations the reliability meter 126 may consider one or more parameters that correspond to a neighbor storage element of the storage element when determining the reliability data 128 of the storage element. For example, formation of a conductive path of and/or operation of the neighbor storage element may impact operation and/or a reliability of the storage element. Accordingly, the reliability meter 126 may compare the one or more neighbor parameters to corresponding thresholds and/or threshold ranges to determine a status of the storage element. To illustrate, if a particular neighbor parameter (e.g., a number of voltage pulses to form the conductive path of the neighbor storage element) is greater than or equal to a threshold, the reliability meter 126 may generate the reliability data 128 to indicate that the storage element has an unhealthy status. In some implementations, the neighbor storage element may be adjacent to the element. In other implementations, the neighbor storage element may not be adjacent to the storage element, but can be included in a same page, wordline, vertical bit line, stack, block, or die of the memory 130 as the storage element.

After generating the reliability data (e.g., health data) for multiple storage elements of the memory 130, the reliability meter 126 may be configured to generate reliability data (e.g., health data) for one or more regions of the memory 130, such as reliability data corresponding to a page, a wordline, a vertical bit line, a comb, a block, a die, or a meta-block, as illustrative, non-limiting examples. For example, the reliability meter 126 may determine a number of the storage elements included in a region and associated with an unhealthy status. The reliability meter 126 may indicate that the region has an unhealthy status in response to the number of storage elements being greater than or equal to a threshold number. To illustrate, when the number of storage elements within a page of the memory 130 is greater than a correction capability of a decoder that may operate in conjunction with the memory 130, the reliability meter 126 may generate reliability data that indicates the page has an unhealthy status, such as a status of faulty. The reliability meter 126 may be configured to include the health status of one or more regions of the memory in the reliability data 128.

After the reliability data 128 is generated, the reliability data 128 may be stored at a location associated with the memory 130. In some implementations, the reliability data 128 may be stored at the memory 130 (e.g., the resistance-based memory) at a region of the memory 130 having a status of healthy. In other implementations, the reliability data 128 may be stored in another memory that is distinct from the memory 130. The other memory and the memory 130 may be included in a data storage device, such that the data storage device can access the reliability data 128 corresponding to the memory 130 from the other memory. For example, the other memory may include a random access memory (RAM) of the data storage device.

During operation of the formation device 110, the formation device 110 may receive the memory 130. The controller 112 may initiate the path generator 124 to apply one or more voltage pulses to the storage element 132 to attempt to form the conductive path 178 through the storage element 132.

During application of the one or more voltage pulses, the monitor/test circuitry 120 may monitor one or more parameters associated with formation of the conductive path 178. For example, the monitor/test circuitry 120 may identify a transition of the storage element 132 from the first state (e.g., the virgin state) to the second state (e.g., the set state or the reset state) which indicates formation of the conductive path 178. Based on the transition being detected, the path generator 124 may stop applying one or more voltage pulses to the storage element 132 to form the conductive path 178. After the path generator 124 stops applying the one or more voltage pulses, the monitor/test circuitry 120 may perform one or more tests on the storage element 132. Based on the one or more parameters monitored by the monitor/test circuitry 120 and/or the one or more test performed by the monitor/test circuitry 120, the monitor/test circuitry may generate the parameter data 122 corresponding to the storage element 132. The reliability meter 126 may access the parameter data 122 and generate the reliability data 128 corresponding to the storage element 132, a region of the memory 130 that includes the storage element 132, a neighboring storage element of the storage element 132, a region of the memory 130 that includes the neighboring storage element, or a combination thereof, as illustrative, non-limiting examples.

In some implementations, when conductive paths are concurrently formed in multiple storage elements, the monitor/test circuitry 120 may monitor the multiple storage elements during the forming stage 182 and identify one or more storage elements having parameters (e.g., characteristics) that deviate from parameters of the multiple storage elements. For example, if the forming stage is performed on ten storage elements in parallel, the monitor/test circuitry 120 may generate a flag for each storage element having a particular parameter that differs from an average parameter value of the ten storage elements. To illustrate, a flag may be generated in response to a particular storage element of the multiple storage elements having a monitored current value during the formation stage that varies by more than ±10% of an average monitored current value of the multiple storage elements during the formation stage. The flag may be included in the parameter data 122 and may be used by the reliability meter 126 to generate the reliability data 128. For example, the flag may indicate that a corresponding particular storage element is unhealthy.

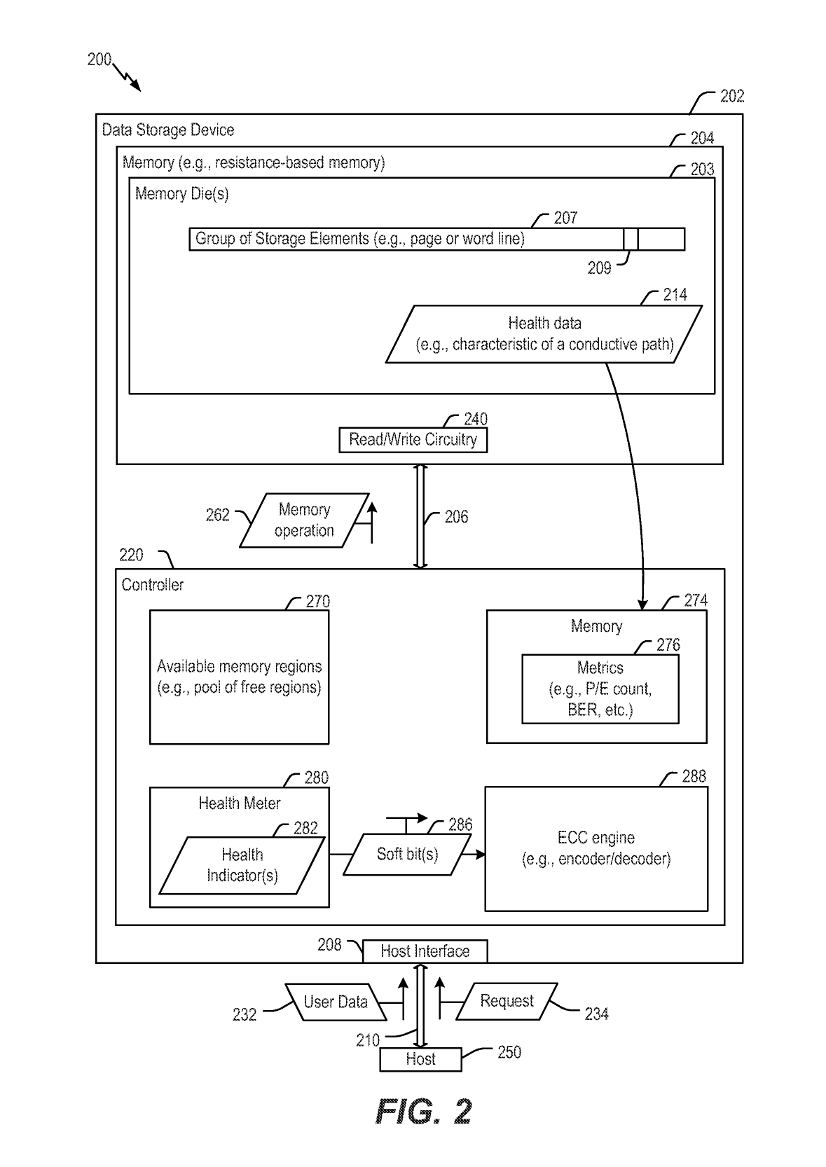

By recording the parameter data 122 during formation of the conductive path 178, the reliability meter 126 may identify the storage element 132 as “problematic” (e.g., has a status of unhealthy or a status of faulty). Additionally, the reliability meter 126 may also identify one or neighboring storage elements that may be problematic based on formation of the channel 178 of the storage element 132 and/or may identify one or more regions (e.g., that include the storage element 132) of the memory 130 that may be problematic. Accordingly, the storage element 132, the one or more neighboring storage elements, and/or the one or more regions may each be identified as problematic prior to the memory 130 being used as part of a data storage device. By making the reliability data 128 available to the data storage device that includes the memory 130, the data storage device may improve an operational performance of the memory, as described with reference to FIG. 2.

Referring to FIG. 2, a particular illustrative embodiment of a system is depicted and generally designated 200. The system 200 includes a data storage device 202 and a host device 250. The data storage device 202 includes a controller 220 and a memory 204, such as a non-volatile memory, that is coupled to the controller 220.

The controller 220 may be configured to use health data 214 associated with the memory 204 to determine one or more health statuses (e.g., one or more health indicators) associated with the memory 204. The health data 214 may include or correspond to reliability data associated with a characteristic of a conductive path of a storage element of the memory 204 (e.g., a resistance-based memory). For example, the health data 214 may include and/or may have been generated based on data gathered during or based on a formation stage configured to form the conductive path of the storage element. The health data 214 may include or correspond to the reliability data 128 of FIG. 1. As an illustrative example, the health data 214 may indicate that a particular storage element of the memory 204 has a particular status of multiple health statuses and/or may include one or more parameters (e.g., the parameter data 122 of FIG. 1) associated with the particular storage element. The controller 220 may use the health data 214 (e.g., the reliability data) to perform one or more memory operations, as described further herein.

The data storage device 202 and the host device 250 may be operationally coupled via a connection (e.g., a communication path 210), such as a bus or a wireless connection. The data storage device 202 may be embedded within the host device 250, such as in accordance with a Joint Electron Devices Engineering Council (JEDEC) Solid State Technology Association Universal Flash Storage (UFS) configuration. Alternatively, the data storage device 202 may be removable from the host device 250 (i.e., “removably” coupled to the host device 250). As an example, the data storage device 202 may be removably coupled to the host device 250 in accordance with a removable universal serial bus (USB) configuration. In some implementations, the data storage device 202 may include or correspond to a solid state drive (SSD), which may be used as an embedded storage drive (e.g., a mobile embedded storage drive), an enterprise storage drive (ESD), a client storage device, or a cloud storage drive, as illustrative, non-limiting examples.

The data storage device 202 may be configured to be coupled to the host device 250 via the communication path 210, such as a wired communication path and/or a wireless communication path. For example, the data storage device 202 may include an interface 208 (e.g., a host interface) that enables communication via the communication path 210 between the data storage device 202 and the host device 250, such as when the interface 208 is communicatively coupled to the host device 250.

For example, the data storage device 202 may be configured to be coupled to the host device 250 as embedded memory, such as eMMC® (trademark of JEDEC Solid State Technology Association, Arlington, Va.) and eSD, as illustrative examples. To illustrate, the data storage device 202 may correspond to an eMMC (embedded MultiMedia Card) device. As another example, the data storage device 202 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 202 may operate in compliance with a JEDEC industry specification. For example, the data storage device 202 may operate in compliance with a JEDEC eMMC specification, a JEDEC Universal Flash Storage (UFS) specification, one or more other specifications, or a combination thereof.

The host device 250 may include a processor and a memory. The memory may be configured to store data and/or instructions that may be executable by the processor. The memory may be a single memory or may include one or more memories, such as one or more non-volatile memories, one or more volatile memories, or a combination thereof. The host device 250 may issue one or more commands to the data storage device 202, such as one or more requests to erase data at, read data from, or write data to the memory 204 of the data storage device 202. For example, the host device 250 may be configured to provide data, such as user data 232, to be stored at the memory 204 or to request data to be read from the memory 204. The host device 250 may include a mobile telephone, a music player, a video player, a gaming console, an electronic book reader, a personal digital assistant (PDA), a computer, such as a laptop computer or notebook computer, any other electronic device, or any combination thereof, as illustrative, non-limiting examples.

The host device 250 communicates via a memory interface that enables reading from the memory 204 and writing to the memory 204. For example, the host device 250 may operate in compliance with a Joint Electron Devices Engineering Council (JEDEC) industry specification, such as a Universal Flash Storage (UFS) Host Controller Interface specification. As other examples, the host device 250 may operate in compliance with one or more other specifications, such as a Secure Digital (SD) Host Controller specification, as an illustrative, non-limiting example. The host device 250 may communicate with the memory 204 in accordance with any other suitable communication protocol.

The memory 204 of the data storage device 202 may include a non-volatile memory. The memory 204 may have a three-dimensional (3D) memory configuration. Alternatively, the memory 204 may have another configuration, such as a two-dimensional (2D) memory configuration. The memory 204 may include a resistance-based memory, such as a resistive random access memory (ReRAM). For example, the memory 204 may include or correspond to the memory 130 of FIG. 1.

The memory 204 may include one or more memory dies 203. Each of the one or more memory dies 203 may include one or more blocks (e.g., one or more erase blocks). Each block may include one or more groups of storage elements, such as a representative group of storage elements 207. The group of storage elements 207 may be configured as a page or a word line. The group of storage elements 207 may include multiple storage elements (e.g., memory cells), such as a representative storage element 209. The memory 204 may include (e.g., store) the health data 214. The health data 214 may include or correspond to the reliability data 128 of FIG. 1. The health data 214 may be associated with a characteristic of a conductive path of a storage element of the memory 204 (e.g., a resistance-based memory). For example, the health data 214 may indicate a health (e.g., a reliability) of a particular storage element, a region of the memory 204 that includes the particular storage element, a neighboring storage element of the particular storage element, a region of the memory 204 that includes the neighboring storage element, or a combination thereof, as illustrative, non-limiting examples.

The memory 204 may include support circuitry, such as read/write circuitry 240, to support operation of the one or more memory dies 203. Although depicted as a single component, the read/write circuitry 240 may be divided into separate components of the memory 204, such as read circuitry and write circuitry. The read/write circuitry 240 may be external to the one or more memory dies 203 of the memory 204. Alternatively, one or more individual memory dies may include corresponding read/write circuitry that is operable to read from and/or write to storage elements within the individual memory die independent of any other read and/or write operations at any of the other memory dies.

The data storage device 202 includes the controller 220 coupled to the memory 204 (e.g., the one or more memory dies 203) via a bus 206, an interface (e.g., interface circuitry), another structure, or a combination thereof. For example, the bus 206 may include multiple distinct channels to enable the controller 220 to communicate with each of the one or more memory dies 203 in parallel with, and independently of, communication with the other memory dies 203. In some implementations, the memory 204 may be a flash memory.

The controller 220 is configured to receive data and instructions from the host device 250 and to send data to the host device 250. For example, the controller 220 may send data to the host device 250 via the interface 208, and the controller 220 may receive data from the host device 250 via the interface 208. The controller 220 is configured to send data and commands to the memory 204 and to receive data from the memory 204. For example, the controller 220 is configured to send data and a write command to cause the memory 204 to store data to a specified address of the memory 204. The write command may specify a physical address of a portion of the memory 204 (e.g., a physical address of a word line of the memory 204) that is to store the data. The controller 220 may also be configured to send data and commands to the memory 204 associated with background scanning operations, garbage collection operations, and/or wear-leveling operations, as illustrative, non-limiting examples. The controller 220 is configured to send a read command to the memory 204 to access data from a specified address of the memory 204. The read command may specify the physical address of a region of the memory 204 (e.g., a physical address of a word line of the memory 204).

The controller 220 may include available memory regions 270, a memory 274, a health meter 280, and an error correction code (ECC) engine. The available memory regions 270 may indicate a pool of free regions of the memory 204, such as one or more regions available to store data as part of a write operation. For example, the available memory regions 270 may be organized as a table or other data structure that is configured to track free regions of the memory 204 that are available for write operations. The memory 274 may include one or more metrics 276 associated with use of the memory 204. The metrics 276 may be tracked on a storage element-by-storage element basis, on a wordline-by-wordline basis, on a block-by-block basis, on a die-by-die basis, and/or other basis, as illustrative, non-limiting examples. The one or more metrics 276 may track a program/erase (P/E) count (PEC), a bit error rate (BER), a programming time, an erase time, a number of voltage pulses to program a storage element, a number of voltage pulses to erase a storage element, one or more other metrics corresponding to the memory 204, or a combination thereof, as illustrative, non-limiting examples. In some implementations, the health data 214 or a copy thereof may be stored at the memory 274.

The health meter 280 may be configured to determine a health indicator 282 (e.g., one or more health indicators) associated with the memory 204. For example, the health meter 280 may apply a health scheme to one or more of the metrics 276, to the health data 214, or a combination thereof, to generate the health indicators 282. In some implementations, the health meter 280 may be configured to perform one or more operations as described with reference to the reliability meter 126 of FIG. 1.

The health indicators 282 may be stored at the health meter 280, at the memory 274, and/or at the memory 204. In some implementations, the health meter 280 may be configured to provide a soft bit 286 (e.g., one or more soft bits) to the ECC engine 288. The health meter 280 may generate the soft bit 286 based on the health data 214, the metrics 276, the health indicators 282, or a combination thereof. The soft bit 286 may indicate a reliability of a storage element of the memory 204 that is used during a decode operation performed by the ECC engine 288. In other implementations, the health meter 280 may provide reliability data (corresponding to the storage element) other than the soft bit 286 to the ECC engine 288. For example, the health meter 280 may provide reliability data to the ECC engine 288 that indicates that the storage element is faulty (e.g., a determined by the health meter 280 based on the health data 214).

The ECC engine 288 may be configured to receive data, such as the user data 232, and to generate one or more error correction code (ECC) codewords (e.g., including a data portion and a parity portion) based on the data. For example, the ECC engine 288 may include an encoder configured to encode the data using an ECC encoding technique. The ECC engine 288 may include a Reed-Solomon encoder, a Bose-Chaudhuri-Hocquenghem (BCH) encoder, a low-density parity check (LDPC) encoder, a turbo encoder, an encoder configured to encode the data according to one or more other ECC techniques, or a combination thereof, as illustrative, non-limiting examples.

The ECC engine 288 may include a decoder configured to decode data read from the memory 204 to detect and correct bit errors that may be present in the data. For example, the ECC engine 288 may correct a number of bit errors up to an error correction capability of an ECC technique used by the ECC engine 288. A number of errors identified by the ECC engine 288 may be tracked by the controller 220, such as by the ECC engine 288. For example, based on the number of errors, the ECC engine 288 may determine a bit error rate (BER) associated with one or more regions of the memory 204.

During operation of the data storage device 202, the controller 220 may receive a request 234 from the host device to perform a memory operation 262. In some implementations, the controller 220 may generate a request to perform a memory operation associated with the memory 204. The memory operation may include or correspond to a write operation, a read operation, a folding operation, a wear-leveling operation, a garbage collection operation, an erase operation, one or more other operations, or a combination thereof, as illustrative, non-limiting examples. For example, the memory operation may include one or more sub-operations to be performed. To illustrate, a garbage collection operation may include a first sub-operation to read data from a particular region of the memory 204 and a second sub-operation to write data to an available region of the memory 204 identified based on the available memory regions 270.

During a write operation, data may be written to one or more storage elements. During a read operation, data may be read from one or more storage elements. During a folding operation, an internal transfer may occur at the memory 204 where data stored at single-level cell (SLC) pages is read and stored at one or more multi-level cell (MLC) pages. During a wear-leveling operation and/or a garbage collection operation, data may be transferred within the memory 204 for purposes of equalizing wear of different regions of the memory 204 and/or for gathering defragmented data into one or more consolidated regions of the memory 204. During an erase operation, data may be erased from one or more storage elements of the memory 204.

Responsive to the request 234, the controller may determine a health indicator associated with a storage element of the memory 204. For example, the health meter 280 may generate and/or access a health indicator corresponding to the storage element. The health indicator corresponding to the storage element may be based on the health data 214 that correspond to the storage element, such as reliability data based on a characteristic of a conductive path associated with the storage element. The controller 220 may initiate a memory operation 262 to be performed at a region (e.g., one or more storage elements) of the memory 204 that includes the storage element. For example, the region may correspond to a vertical bit line, a finger, a comb, a block, or a die of the memory 204 that includes the storage element. The memory operation 262 may be performed based at least in part on the health indicator. In some implementations, the memory operation 262 may include or correspond to a sub-operation of the memory operation that corresponds to the request 234.

To illustrate, the controller 220 may be configured to initiate the memory operation 262 at a particular storage element of the multiple storage elements of the memory 204. The particular storage element may be selected from the available memory regions 270 based on a value of a health indicator associated with the particular storage element. For example, based on a memory operation (or a sub-operation) to write data to the memory 204, the controller 220 may identify a “healthiest” region (or a region that is healthier than a threshold level) of the available memory regions 270 based on the health data 214 and/or the health indicators 282 that correspond to one or more regions included in the available memory regions 270. The identified region may be used to perform the write operation. To illustrate, the region (e.g., a storage element) may be selected to be used to perform the memory operation 262 according to a wear-leveling technique. The wear-leveling technique may direct one or more first storage elements having a first status of healthy (as indicated by the health data 214) to be selected prior to one or more second storage elements having a second status of unhealthy (as indicated by the health data 214). In some implementations, one or more storage elements having a status of unhealthy or faulty (as indicated by the health data 214) may be maintained by the controller 220 as reserved storage elements, such that the one or more storage elements are used when no healthy storage elements (or regions) are available.

In some implementations, the controller 220 may detect that the memory operation 262 is associated with storing priority data at the memory 204. Accordingly, the controller 220 may identify a storage element (or region) of the memory 204 having a corresponding health indicator or corresponding health data that indicates that the storage element (or the region) has a status of healthy. The storage element (or the region) may be selected to store the priority data responsive to a determination that the storage element (or the region) has the status of healthy.

In some implementations, the controller 220 may identify a first value to be written to a particular storage element based on the memory operation 262 (e.g., a write operation). The first value may correspond to a first resistive state of the storage element, such a low resistance state. For example, the controller 220 may identify the first value that is provided by the ECC engine 288 (e.g., an encoder) and that is to be written to the particular storage element. The controller 220 may determine a status, such as a health status, corresponding to the particular storage element based on a health indicator and/or health data 214 corresponding to the particular storage element. The controller 220 may modify the first value based on the status of the particular storage element being unhealthy or faulty. For example, the controller 220 may modify the first value to generate a second value that corresponds to a second resistive state of the storage element, such as a high resistance state. The second value may be programmed at the particular storage element based on execution of the memory operation 262. By changing the value stored at the particular storage element, the controller 220 may reduce an amount of leakage current from the particular storage element that is known to be unhealthy or faulty. Additionally, based on a read operation of the particular storage element, one or more soft bits may be provided to the ECC engine 288 (e.g., a decoder) that indicate that the value read from the particular storage element is unreliable.

In some implementations, when the memory operation 262 includes a read operation, the read operation may be performed at a storage element to read a data value from the storage element. The data value read from the storage element may be provided to the ECC engine 288 (e.g., a decoder). Additionally the soft bit 286 may be provided to the ECC engine 288 responsive to the data value being read from the storage element. The soft bit 286 may correspond to the storage element and may indicate a reliability of the storage element that is based on a health indicator and/or the health data 214 that corresponds to the storage element. For example, when the health indicator and/or the health data 214 indicate that the storage element has a status of faulty, the soft bit 286 may include a value that indicates that the storage element is unreliable. Accordingly, the ECC engine 288 (e.g., the decoder) may be configured to receive, from the controller 220, the soft bit 286 corresponding to the storage element based on a read operation performed on the storage element.

In some implementations, when the memory operation 262 includes a read operation, the read operation may be performed at a neighbor storage element of the storage element. The controller 220 may be configured to provide a soft bit to the ECC engine responsive to the read operation, where the soft bit corresponds to the neighbor storage element. The soft bit that corresponds to the neighbor storage element may be determined based on the health indicator and/or the health data 214 corresponding to the storage element. For example, if the health indicator and/or the health data 214 indicate that the storage element has a status of unhealthy or faulty, the soft bit 286 corresponding to the neighbor storage element may include a value that indicates that the neighbor storage element is unreliable. To illustrate, the health data 214 of the storage element may indicate that the storage element is unhealthy or faulty based on too high of a voltage being applied to the storage element during formation of a conductive path of the storage element. The excessive voltage applied to the storage element may have damaged one or more neighboring storage elements and caused the one or more neighboring storage elements to be considered unreliable.

In some implementations, the read/write circuitry 240 may modify one or more parameters based on the health indicator and/or the health data 214 corresponding to the storage element. In some implementations, the read/write circuitry 240 may access the health data 214 to modify the one or more parameters. For example, when the storage element is associated with a status of unhealthy, a write parameter (e.g., a number of write voltage pulses, a value of a voltage bias) associated with writing first data to the storage element may be modified. As another example, when the storage element is associated with a status of unhealthy, a read parameter (e.g., a read threshold voltage, a value of a voltage bias, a number of read pulses, and/or an amount to increase voltage levels between consecutive read pulses) associated with reading second data from the storage element may be modified.

In some implementations, the metrics 276, the available memory regions 270, the health indicators 282, the health data 214, or a combination thereof, may be stored at the memory 204. In other implementations, the metrics 276, the available memory regions 270, the health indicators 282, the health data 214, or a combination thereof, may be stored at the memory 274, such as a random access memory (RAM). Alternatively, or in addition, the metrics 276, the available memory regions 270, the health indicators 282, the health data 214, or a combination thereof, may be stored in another memory that is distinct from the memory 204 and the memory 274. The other memory, such as a non-volatile memory or a volatile memory, may be included in or coupled to the controller 220. The other memory may be a single memory component, may include multiple distinct memory components, and/or may indicate multiple different types (e.g., volatile memory and/or non-volatile) of memory components. In some embodiments, the other memory may be included in the host device 250.

Although FIG. 2 has been described as the health data 214 corresponding to one or more storage elements of the memory 204, in other implementations the health data 214 may correspond to another memory, such as the memory 274. For example, the memory 274 may include or correspond to the memory 130 of FIG. 1. In some implementations, both the memory 204 and the memory 274 may have corresponding health data.

Although one or more components of the data storage device 202 have been described with respect to the controller 220, in other implementations certain components may be included in the memory 204. For example, at least one of the available memory regions 270, the memory 274, the health meter 280, or the ECC engine 288 may be included in the memory 204. Alternatively, or in addition, one or more functions as described above with reference to the controller 220 may be performed at or by the memory 204. For example, one or more functions of the available memory regions 270, the memory 274, the health meter 280, or the ECC engine 288 may be performed by components and/or circuitry included in the memory 204. Alternatively, or in addition, one or more components of the data storage device 202 may be included in the host device 250. For example, one or more of the available memory regions 270, the memory 274, the health meter 280 or the ECC engine 288 may be included in the host device 250. Alternatively, or in addition, one or more functions as described above with reference to the controller 220 may be performed at or by the host device 250. In some implementations, the health data 214 corresponding to the memory 204 may be stored at a memory of the host device 250. The health data 214 stored at the host device 250 may be provided to and/or accessible to the controller 220 and/or one or more other components of the data storage device 202.

By using the health data 214 that is based on a characteristic of a conductive path associated with a storage element of the memory 204, the data storage device 202 may rely on information gathered with respect to one or more storage elements prior to the memory 204 being used as part of the data storage device 202. Accordingly, the data storage device 202 may make decisions regarding one or more memory operations based on factors that are not measureable by an amount of use of the memory 204, such as one or more of the metrics 276 which are based on an amount of use of the memory 204. By using the health data 214, the data storage device 202 may improve use of the memory 204 to reduce power consumption, shorten program and erase times, increase data retention, increase reliability, and/or increase operating life of the memory 204, as illustrative, non-limiting examples.

FIG. 3 is a diagram of a particular embodiment of a memory device that is generally designated 300. The memory device 300 may be included in a data storage device, such as the data storage device 202 of FIG. 2. The memory device 300 includes the memory 204 (e.g., a resistance-based memory). The memory 204 may include or correspond to the memory 130 of FIG. 1. FIG. 3 illustrates a portion of a three-dimensional architecture of the memory 204, such as a resistive random access memory (ReRAM). In the embodiment illustrated in FIG. 3, the memory 204 (e.g., the resistance-based memory, such as a ReRAM) includes a plurality of conductive lines in physical layers over a substrate (e.g., substantially parallel to a surface of the substrate), such as representative wordlines 320, 321, 322, and 323 (only a portion of which is shown in FIG. 3) and a plurality of vertical conductive lines through the physical layers, such as representative bit lines 310, 311, 312, and 313.

The memory 204 also includes a plurality of resistance-based storage elements (e.g., memory cells), such as representative storage elements 330, 331, 332, 340, 341, and 342, each of which is coupled to a bit line and a wordline in arrays of memory cells in multiple physical layers over the substrate (e.g., a silicon substrate). The storage elements 330, 331, 332, 340, 341, and 342 may include or correspond to the storage elements 132, 134 of FIG. 1 or the storage element 209 of FIG. 2. The memory 204 also includes read/write circuitry 240 of FIG. 2. The read/write circuitry 240 is coupled to wordline drivers 308 and bit line drivers 306. Although the read/write circuitry 240 is illustrated as a single component, in some implementations, the read/write circuitry 240 may be divided into separate components of the memory 204, such as read circuitry and write circuitry.

In the embodiment illustrated in FIG. 3, each of the wordlines includes a plurality of fingers (e.g., a first wordline 320 includes fingers 324, 325, 326, and 327). Each finger may be coupled to more than one bit line. To illustrate, a first finger 324 of the first wordline 320 is coupled to a first bit line 310 via a first storage element 330 at a first end of the first finger 324 and is coupled to a second bit line 311 via a second storage element 340 at a second end of the first finger 324. As illustrated in FIG. 3, the fingers of the wordline 320 and the fingers of the wordline 323 may be interlaced, such that a finger of the wordline 323 is positioned between the finger 325 and the finger 327 of the wordline 320 and such that the finger 327 is positioned between two fingers of the wordline 323. A comb may be a designation of a region (e.g., a structural designation) of the memory 204 that includes a group of two or more wordlines that are interlaced. For example, the wordline 323 and the wordline 320 may be associated with a comb. In some implementations, a comb may include a first set of wordlines (e.g., a first stack of wordline) and a second set of wordline (e.g., a second stack of wordlines). For example, the first set of wordlines may include the wordlines 320, 321, 322 and the second set of wordlines may include the wordline 323 and additional wordlines included in a stack with the wordline 323.

In the embodiment illustrated in FIG. 3, each bit line may be coupled to more than one wordline. To illustrate, the first bit line 310 is coupled to the first wordline 320 via the first storage element 330 and is coupled to a third wordline 322 via a third storage element 332. Each bit line may be referred to as a vertical bit line. In some implementations, each storage element coupled to a particular vertical bit line may be considered to be part of the vertical bit line.

During a write operation, a controller, such as the controller 220 of FIG. 2, may generate data (e.g., control data) or may receive data (e.g., user data) from a host device, such as the host device 250 of FIG. 2. The controller may send the data (or a representation of the data) to the memory device 300. For example, the controller may encode the data prior to sending the encoded data to the memory device 300.

The read/write circuitry 240 may write the data to storage elements corresponding to the destination of the data. For example, the read/write circuitry 240 may apply selection signals to selection control lines coupled to the wordline drivers 308 and the bit line drivers 306 to cause a write voltage to be applied across a selected storage element. For example, to select the first storage element 330, the read/write circuitry 240 may activate the wordline drivers 308 and the bit line drivers 306 to drive a programming current (also referred to as a write current) through the first storage element 330. To illustrate, a first write current may be used to write a first logical value (e.g., a value corresponding to a high-resistance state) to the first storage element 330, and a second write current may be used to write a second logical value (e.g., a value corresponding to a low-resistance state) to the first storage element 330. The programming current may be applied by generating a programming voltage across the first storage element 330 by applying a first voltage to the first bit line 310 and to wordlines other than the first wordline 320 and applying a second voltage to the first wordline 320. In a particular embodiment, the first voltage is applied to other bit lines (e.g., the bit lines 314, 315) to reduce leakage current in the memory 204.

Additionally, the controller may access the data stored at the memory 204. The controller may cause the read/write circuitry 240 to read bits from particular storage elements of the memory 204 by applying selection signals to selection control lines coupled to the wordline drivers 307 and the bit line drivers 306 to cause a read voltage to be applied across a selected storage element. For example, to select the first storage element 330, the read/write circuitry 240 may activate the wordline drivers 308 and the bit line drivers 306 to apply a first voltage (e.g., 0.7 volts (V)) to the first bit line 310 and to wordlines other than the first wordline 320. A lower voltage (e.g., 0 V) may be applied to the first wordline 320. Thus, a read voltage is applied across the first storage element 330, and a read current corresponding to the read voltage may be detected at a sense amplifier of the read/write circuitry 240. The read current corresponds (via Ohm's law) to a resistance state of the first storage element 330, which corresponds to a logical value stored at the first storage element 330. The logical value read from the first storage element 330 and other elements read during the read operation may be provided to the controller.

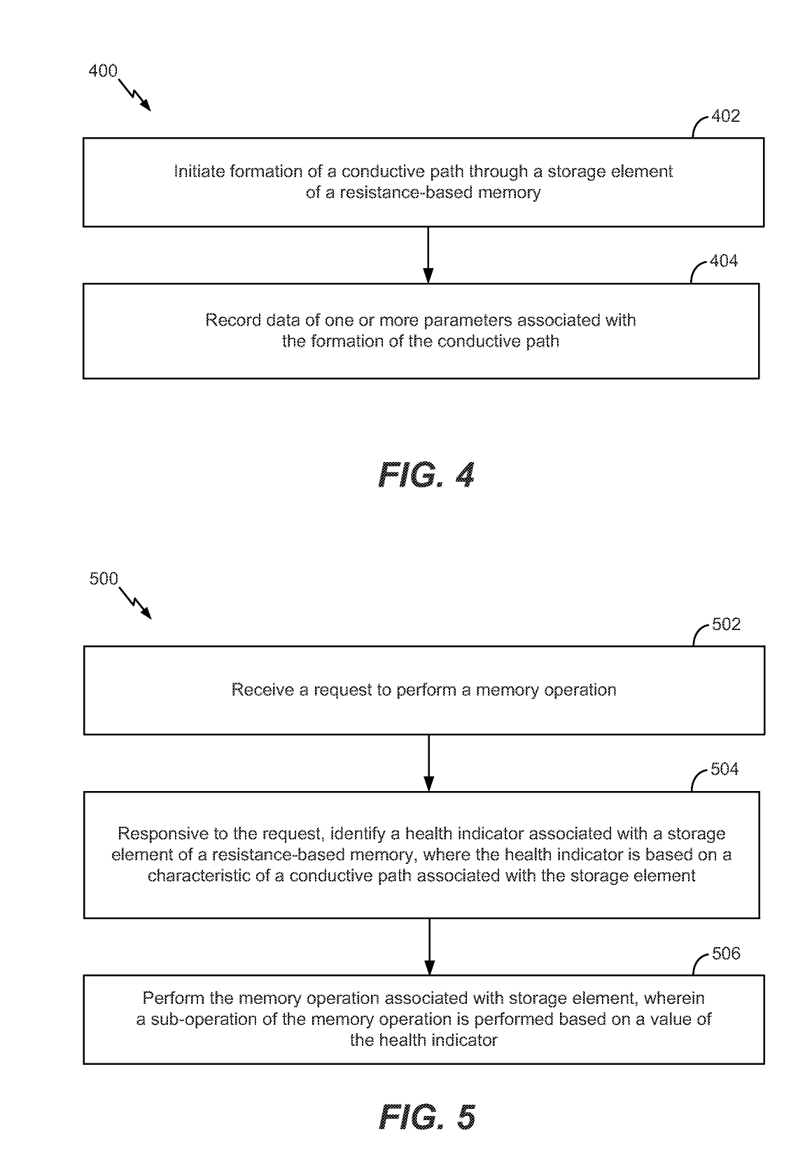

Referring to FIG. 4, a particular illustrative embodiment of a method is depicted and generally designated 400. For example, the method 400 may be associated with fabricating a resistance-based memory. The method 400 may be performed at the formation device 110, such as by the controller 112, the monitor/test circuitry 120, and/or another component of the formation device 110, as illustrative, non-limiting examples.

The method 400 includes initiating formation of a conductive path through a storage element of a resistance-based memory, at 402. For example, example the resistance-based memory may include or correspond to the memory 130 of FIG. 1 or the memory 204 of FIG. 2. The storage element may include or correspond to the storage element 132, the storage element 134 of FIG. 1, or the storage element 209 of FIG. 2. The conductive path may include or correspond to the conductive path 178 of FIG. 1. The conductive path is formed by initializing the storage element to change a state of the storage element from a particular state to another state. For example, the conductive path may be formed by initializing the storage element to change a state of the storage element from a first state (e.g., a pre-formation state that corresponds to a first resistance state) to a second state (e.g., a post-formation state, such as a set state that corresponds to a second resistance state or a reset state that corresponds to a third resistance state). To illustrate, the conductive path may be formed by applying a set of one or more voltage pulses to the storage element to cause the state of the storage element to change. In some implementations, the resistance-based memory may include a three-dimensional (3D) memory configuration that is monolithically formed in one or more physical levels of arrays of memory cells having an active area disposed above a silicon substrate, and where the resistance-based memory includes circuitry associated with operation of the memory cells.

The method 400 also includes recording data of one or more parameters associated with the formation of the conductive path, at 404. For example, the one or more parameters may be recorded by (e.g., generated by) monitor circuitry, test circuitry, or a combination thereof, such as the monitor/test circuitry 120 of FIG. 1. The data of the one more parameters may include or correspond to the parameter data 122 of FIG. 1. For example, the one or more parameters may include or correspond to a resistance of the storage element that indicates successful formation of the conductive path, a first amount of current through a region of the resistance-based memory that includes the storage element based on a first test voltage applied to the region after formation of the conductive path, a first amount of leakage current through a neighbor storage element of the storage element based on a second test voltage applied to the storage element after formation of the conductive path, a second amount of leakage current through the storage element based on a third test voltage applied to a neighbor storage element of the storage element after formation of the conductive path, or a combination thereof, as illustrative, non-limiting examples. Additionally or alternatively, the one or more parameters may include a number of voltage pulses applied to the storage element to form the conductive path, an intensity of the voltage pulses, a second amount of current through the storage element during formation of the conductive path, a second amount of leakage current through the neighbor storage element during formation of the conductive path, or a combination thereof, as illustrative, non-limiting examples. The data of the one or more parameters may be included in or may be used to generate reliability data, such as health data, associated with the storage element. For example, the reliability data may indicate that the storage element has a particular status of multiple health statuses, as illustrative, non-limiting examples. The reliability data may include or correspond to the reliability data 128 of FIG. 1 or the health data 214 of FIG. 2. The reliability data may be stored at the resistance-based memory, at another memory, or a combination thereof.

In some implementations, the reliability data may be generated based on at least one parameter of the one or more parameters that fails to satisfy a target threshold or is outside of a target range. For example, the reliability data corresponding to the storage element may be generated in response to the at least one parameter failing to satisfy the target threshold or being outside of the target range. To illustrate, a set of one or more voltage pulses may be applied to the storage element until detecting a transition of the storage element from a pre-forming state to a post-forming state. A number of the voltage pulses applied to the storage element to form the conductive path may be determined and compared to a first threshold value or to a first threshold range. Health data may be generated to indicate that the storage element has a particular status of multiple health statues based on the number being greater than or equal to the first threshold value or being outside of the first threshold range. For example, the reliability meter 126 of FIG. 1 may be configured to generate the health data.

Alternatively, or in addition, an intensity value associated with the one or more voltage pulses applied to the storage element to form the conductive path may be determined and compared to a second threshold value or to a second threshold range. The intensity value may be based on a total duration of the one or more voltage pulses applied to the storage element to form the conductive path, an amount of voltage applied to the storage element to form the conductive path, a number of the one or more voltage pulses applied to the storage element to form the conductive path, a total amount of power delivered to the storage element to form the conductive path, or a combination thereof, as illustrative, non-limiting examples. The intensity value may be generated by the monitor/test circuitry 120 and/or may be included in the parameter data 122 of FIG. 1. Health data may be generated to indicate that the storage element has a particular status of multiple health statuses based on the intensity value being greater than or equal to the second threshold value or being outside of the second threshold range.

In some implementations, particular health data may be generated to indicate that a neighboring storage element of the storage element has a particular status of multiple health statuses. The particular health data may be generated based on a number of voltage pulses of a set of one or more voltage pulses applied to the storage element to form the conductive path being less than or equal to a first threshold value, the number of voltage pulses being greater than or equal to a second threshold value, an intensity value associated with the set of one or more voltage pulses being less than or equal to a third threshold value, the intensity value being greater than or equal to a fourth threshold value, or a combination thereof, as illustrative, non-limiting examples.

After an attempt to form the conductive path, a determination may be made whether the storage element is in a particular state (e.g., a pre-conductive path formation state). For example, the determination may be made by the monitor/test circuitry 120 of FIG. 1. If the storage element is in the particular state after the attempt, an indication may be generated and included in the parameter data 122. The indication may indicate that the formation of the conductive path is unsuccessful. The health data may be generated to indicate that the storage element has a status of faulty based on a determination that the formation of the conductive path is unsuccessful.

After applying the set of one or more voltage pulses to the storage element, the storage element may be programmed to a set state or a reset state and a test voltage may be applied to the storage element. For example, the test voltage may be applied to the storage element after forming the conductive path. Based on the test voltage, a current flow through the storage element may be measured (e.g., identified), such as current flow through the storage element during application of the test voltage. The amount of current may be compared to a threshold or to a threshold range. Alternatively, or in addition, an amount of leakage current associated with a neighboring storage element of the storage element may be measured based on the test voltage applied to the storage element. Health data may be generated (e.g., by the reliability meter 126 of FIG. 1) to indicate that the storage element has a particular status of multiple statuses based on the amount of read current being greater than or equal to the threshold or outside of the threshold range. Alternatively or additionally, another test voltage may be applied to a neighboring storage element of the storage element after formation of the conductive path. An amount of leakage current associated with the storage element based on the test voltage may be determined and stored as part of the parameter data, such as the parameter data 122 of FIG. 1, corresponding to the storage element.

In some implementations, after formation of the conductive path, test data (e.g., a data pattern, random data, or pseudo-random data) may be written to a region of the memory that includes the storage element. Based on the test data stored at the region, a bit-error-rate associated with the region may be determined. An indication of the bit-error-rate (BER) may be stored as part of the data of the one or more parameters associated with the storage element. The bit-error-rate may be indicative of a quality of a forming procedure used to form the conductive path of the storage element. For example, a high bit-error-rate associated with the storage element and/or associated with a region that includes the storage element may indicate that the storage element and/or the region have poor reliability.

In some implementations, formation of a second conductive path through a second storage element of the resistance-based memory may be initiated. For example, the second conductive path and the conductive path (of the storage element) may be formed in parallel (e.g., concurrently).

By recording the data during formation of the conductive channel, one or more regions of the resistance-based memory may be identified as “problematic” (e.g., “unhealthy” or faulty). For example, the one or more regions may be identified as problematic prior to the resistance-based memory being used as part of a data storage device, such as the data storage device 202 of FIG. 2.

Referring to FIG. 5, a particular illustrative embodiment of a method is depicted and generally designated 500. The method 500 may be performed at the data storage device 202, such as by the controller 220, by the health meter 280, by the read/write circuitry 240, or a combination thereof, as an illustrative, non-limiting example.

The method 500 includes receiving a request to perform a memory operation, at 502. For example, the request may include or correspond to the request 234 of FIG. 2. The request may be generated by a controller, such as the controller 220, or by a host device, such as the host device 250, coupled to the data storage device. The memory operation (or a portion of the memory operation) may include or correspond to the memory operation 262 of FIG. 2. In some implementations, the memory operation is a read operation or a write operation.

The method 500 also includes, responsive to the request, identifying a health indicator associated with a storage element of a resistance-based memory, where the health indicator is based on a characteristic of a conductive path associated with the storage element, at 504. For example, the storage element may include or correspond to the storage element 132, the storage element 134 of FIG. 1, or the storage element 209 of FIG. 2. The resistance-based memory may include the memory 130 of FIG. 1 or the memory 204 of FIG. 2. In some implementations, the resistance-based memory may include a three-dimensional (3D) memory configuration that is monolithically formed in one or more physical levels of arrays of memory cells having an active area disposed above a silicon substrate, and where the resistance-based memory includes circuitry associated with operation of the memory cells. The characteristic may correspond to a resistance of the storage element that indicates successful formation of the conductive path. For example, the characteristic is determined based on data collected during a formation stage associated with the conductive path. The health indicator may correspond to a vertical bit line, a page, a wordline, a finger, a comb, a block, a dies, or a meta-block that includes the storage element. The health indicator may be identified (e.g., generated or accessed) by a health meter, such as health meter 280. In some implementations, the health indicator may be generated based on the reliability data 128 of FIG. 1 or the health data 214 of FIG. 2.

The method 500 also includes performing the memory operation associated with the storage element, where a sub-operation of the memory operation is performed based on a value of the health indicator, at 506. The memory operation may be associated with one or more sub-operations that may be performed to execute the memory operation. For example, the one or more sub-operations may include a write operation, a read operation, a folding operation, a wear-leveling operation, an available region selection operation, a garbage-collection operation, or a combination thereof, as illustrative, non-limiting examples.

In some implementations, the data storage device may include circuitry associated with and/or configured to perform one or more memory operations (or one or more sub-operations) at a region of the resistance-based memory. For example, the circuitry may include the memory 130, the reliability meter 126 of FIG. 1, the memory 204, the read/write circuitry 240, the memory 274, the health meter 280, the ECC engine 228 of FIG. 2, other components or circuits, or a combination thereof, as illustrative, non-limiting examples. The region of the resistance-based memory may include the storage element that corresponds to readability data, such as the reliability data 128 of FIG. 1 or the health data 214 of FIG. 2.

By using the health indicator based on a characteristic of a conductive path associated with the storage element, the data storage device may rely on information gathered about the storage element prior to the resistance-based memory being used as part of the data storage device. For example, the information may be gathered during formation of the conductive path of the storage element. Accordingly, the data storage device may make decisions regarding the memory operation based on factors that are not measureable by an amount of use of the resistance-based memory. By using the heath indicator that is based on the information recorded during formation of the conductive channel, the data storage device may improve use of the resistance-based memory to reduce power consumption, shorten program and erase times, increase data retention, increase reliability, and/or increase operating life of the resistance-based memory.

The method 400 of FIG. 4 and/or the method 500 of FIG. 5 may be initiated or controlled by an application-specific integrated circuit (ASIC), a processing unit, such as a central processing unit (CPU), a digital signal processor (DSP), a controller, another hardware device, a firmware device, a field-programmable gate array (FPGA) device, or any combination thereof. As an example, the method 400 of FIG. 4 and/or the method 500 of FIG. 5 can be initiated or controlled by one or more processors, such as one or more processors included in or coupled to a controller. To illustrate, a controller configured to perform the method 400 of FIG. 4 may be able to record data associated with formation of a conductive path of a memory, such as the memory 130 of FIG. 1 or the memory 204 of FIG. 2. Additionally, a controller configured to perform the method 500 of FIG. 5 may be able to perform a memory operation based on a characteristic of a conductive path associated with a memory, such as the memory 130 of FIG. 1 or the memory 204 of FIG. 2.

In an illustrative example, a processor may be programmed to initiate formation of a conductive path through a storage element of a resistance-based memory. For example, the processor may execute instructions to select a location of a storage element, to activate monitoring circuitry, to active a voltage pulse generator. The processor may further execute instructions to record data of one or more parameters associated with the formation of the conductive path. For example, the processor may execute instructions to identify a location of a memory to store the data and to initiate the monitoring circuitry to store the data at the location.

In another illustrative example, a processor may be programmed to receive a request to perform a memory operation. For example, the processor may execute instructions to detect the memory operation, to parse the memory operation, and to identify an op-code of the memory operation. The processor may further execute instructions to, responsive to the request, identifying a health indicator associated with a storage element of a resistance-based memory, where the health indicator is based on a characteristic of a conductive path associated with the storage element. For example, the processor may execute instructions to access health data associated with the storage element, to access a metric associated with the resistance-based memory, and to generate the health indicator. The processor may further execute instructions to perform the memory operation associated with the storage element, where a sub-operation of the memory operation is performed based on a value of the health indicator. For example, the processor may execute instructions to identify the sub-operation, to generate a command corresponding to the sub-operation, to identify a component to execute the sub-operation, and to send the command to the component.

Although various components of the formation device 110 of FIG. 1, the data storage device 202, and/or the host device 250 of FIG. 2 are depicted herein as block components and described in general terms, such components may include one or more microprocessors, state machines, or other circuits configured to enable the various components to perform operations described herein. One or more aspects of the various components may be implemented using a microprocessor or microcontroller programmed to perform operations described herein, such as one or more operations of the method 400 of FIG. 4, and/or the method 500 of FIG. 5. In a particular implementation, each of the controller 112, the memory 114, the monitor/test circuitry 120, the path generator 124, the reliability meter 126 of FIG. 1, the data storage device 202, the memory 204, the read/write circuitry 240, the controller 220, the health meter 280, and/or the ECC engine 288 of FIG. 2 includes a processor executing instructions that are stored at a memory, such as a non-volatile memory of the formation device 110 of FIG. 1, the data storage device 202, or the host device 250 of FIG. 2. Alternatively or additionally, executable instructions that are executed by the processor may be stored at a separate memory location that is not part of the non-volatile memory, such as at a read-only memory (ROM) of the formation device 110 of FIG. 1, the data storage device 202, or the host device 250 of FIG. 2.

With reference to FIG. 2, the data storage device 202 may be attached to or embedded within one or more host devices, such as within a housing of a host communication device (e.g., the host device 250). For example, the data storage device 202 may be integrated within an apparatus such as a mobile telephone, a computer (e.g., a laptop, a tablet, or a notebook computer), a music player, a video player, a gaming device or console, an electronic book reader, a personal digital assistant (PDA), a portable navigation device, or other device that uses non-volatile memory. However, in other embodiments, the data storage device 202 may be implemented in a portable device configured to be selectively coupled to one or more external host devices. For example, the data storage device 202 may be a removable device such as a Universal Serial Bus (USB) flash drive or a removable memory card, as illustrative, non-limiting examples.

The host device 250 may correspond to a mobile telephone, a music player, a video player, a gaming device or console, an electronic book reader, a personal digital assistant (PDA), a computer, such as a laptop, a tablet, or a notebook computer, a portable navigation device, another electronic device, or a combination thereof. The host device 250 may communicate via a host controller, which may enable the host device 250 to communicate with the data storage device 202. The host device 250 may operate in compliance with a JEDEC Solid State Technology Association industry specification, such as an embedded MultiMedia Card (eMMC) specification or a Universal Flash Storage (UFS) Host Controller Interface specification. The host device 250 may operate in compliance with one or more other specifications, such as a Secure Digital (SD) Host Controller specification, as an illustrative example. Alternatively, the host device 250 may communicate with the data storage device 202 in accordance with another communication protocol.

The memory 130 of FIG. 1 (and/or the memory 204 of FIG. 2) may be manufactured using a fabrication process. For example, the fabrication process may include a processor and a memory to initiate and/or control the fabrication process. The memory may include executable instructions such as computer-readable instructions or processor-readable instructions. The executable instructions may include one or more instructions that are executable by a computer such as the processor.

The fabrication process may be implemented by a fabrication system that is fully automated or partially automated. For example, the fabrication process may be automated according to a schedule. The fabrication system may include fabrication equipment (e.g., processing tools) to perform one or more operations to form a memory device. For example, the fabrication equipment may be configured to deposit one or more materials (e.g., layers), etch the one or more layers, form a storage element, form a conductive path through the storage element, perform planarization, etc. In some implementations, the fabrication system may include or correspond to formation device 110 of FIG. 1.

The fabrication system (e.g., an automated system that performs the fabrication process) may have a distributed architecture (e.g., a hierarchy). For example, the fabrication system may include one or more processors, one or more memories, and/or controllers that are distributed according to the distributed architecture. The distributed architecture may include a high-level processor that controls or initiates operations of one or more low-level systems. For example, a high-level portion of the fabrication process may include one or more processors and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component may include one or more processors.

To illustrate, a processor of the fabrication system may be a part of a high-level system, subsystem, or component of the fabrication system. In another embodiment, the processor of the fabrication system includes or is associated with distributed processing at various levels and components of a fabrication system. In some implementations, the formation device 110 may be a low-level system component that includes the controller 112 having one or more processors.

Thus, the processor of the fabrication system may include or have access to processor-executable instructions that, when executed by the processor, cause the processor to initiate or control formation of a memory device, such as the memory 130 of FIG. 1 or the memory 204 of FIG. 2. The memory device may include at least one storage element, where a conductive path is formed through the storage element by applying one or more voltage pulses to the storage element. The memory device may include a memory (e.g., a resistance-based memory) having a three-dimensional (3D) memory configuration that is monolithically formed in one or more physical levels of arrays of storage elements having an active area disposed above the substrate. For example, the storage element may formed by one or more deposition tools, such as molecular beam epitaxial growth tool, a flowable chemical vapor deposition (FCVD) tool, a conformal deposition tool, or a spin-on deposition tool, and by one or more etch removal tools, such as a chemical removal tool.

The executable instructions included in the memory of the fabrication system may enable the processor of the fabrication system to initiate formation of a memory device, such as the memory 130 of FIG. 1 or the memory 204 of FIG. 2. In a particular embodiment, the memory of the fabrication system is a non-transient computer-readable medium storing computer-executable instructions that are executable by the processor to cause the processor to initiate formation of the memory 130 of FIG. 1 or the memory 204 of FIG. 2, in accordance with at least a portion of any of the processes illustrated in FIG. 1, at least a portion of the method of FIG. 4, or any combination thereof. For example, the computer executable instructions may be executable to cause the processor to initiate formation of the memory device, such as the memory 130 of FIG. 1 or the memory 204 of FIG. 2.

The memory 130 of FIG. 1 (and/or the memory 204 of FIG. 2) may have a two-dimensional configuration, a three-dimensional (3D) configuration (e.g., a 3D memory), or any other configuration, and may include a single die or multiple dies (e.g., multiple stacked memory dies). For example, the memory 130 of FIG. 1 (and/or the memory 204 of FIG. 2) may include a resistive random access memory (ReRAM), a three-dimensional (3D) memory, a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), or a combination thereof. Alternatively, or in addition, the memory 130 of FIG. 1 and/or the memory 204 of FIG. 2 may include another type of memory. The memory 130 of FIG. 1 and/or the memory 204 of FIG. 2 may include a semiconductor memory device.

Semiconductor memory devices, such as the memory 130 of FIG. 1 or the memory 204 of FIG. 2, include volatile memory devices, such as dynamic random access memory (“DRAM”) or static random access memory (“SRAM”) devices, non-volatile memory devices, such as magnetoresistive random access memory (“MRAM”), resistive random access memory (“ReRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of a non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor material such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically used for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional illustrative structures described but cover all relevant memory structures within the scope of the disclosure as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method of fabricating a resistance-based memory, the method comprising:
initiating formation of a conductive path through a storage element of the resistance-based memory; and
recording data of one or more parameters associated with the formation of the conductive path.

2. The method of claim 1, wherein the conductive path is formed by applying a set of one or more voltage pulses to the storage element, and further comprising, after applying the set of one or more voltage pulses, applying a test voltage to the storage element after forming the conductive path and identifying a current flow through the storage element during application of the test voltage.

3. The method of claim 1, wherein the one or more parameters includes a first parameter associated with a resistance of the storage element that indicates successful formation of the conductive path, a second parameter associated with a first amount of current through a region of the resistance-based memory that includes the storage element based on a first test voltage applied to the region after the formation of the conductive path, a third parameter associated with a first amount of leakage current through a neighbor storage element of the storage element based on a second test voltage applied to the storage element after the formation of the conductive path, a fourth parameter associated with a second amount of leakage current through the storage element based on a third test voltage applied to the neighbor storage element of the storage element after the formation of the conductive path, a fifth parameter associated with a number of voltage pulses applied to the storage element to form the conductive path, a sixth parameter associated with an intensity of the voltage pulses, a seventh parameter associated with a second amount of current through the storage element during formation of the conductive path, an eighth parameter associated with a second amount of leakage current through the neighbor storage element during formation of the conductive path, or a combination thereof.

4. The method of claim 1, further comprising:
identifying at least one parameter of the one or more parameters that fails to satisfy a target threshold or is outside of a target range;
generating reliability data corresponding to the storage element in response to the at least one parameter failing to satisfy the target threshold or being outside of the target range, wherein the reliability data indicates the storage element has a particular status of multiple health statuses; and
storing the reliability data at the resistance-based memory.

5. The method of claim 1, wherein the conductive path is formed by initializing the storage element to change a state of the storage element from a first state to a second state, wherein the first state is a virgin state that corresponds to a first resistance state, wherein the second state is a set state or a reset state, wherein the set state corresponds to a second resistance state, and wherein the reset state corresponds to a third resistance state.

6. The method of claim 1, wherein the conductive path is formed by initializing the storage element to change a state of the storage element from a particular state to another state, and further comprising:
determining, after an attempt to form the conductive path, whether the storage element is in the particular state, and indicating that the formation of the conductive path is unsuccessful if the storage element is in the particular state after the attempt; and
generating health data to indicate that the storage element has a status of faulty based on a determination that the formation of the conductive path is unsuccessful.

7. The method of claim 1, further comprising:
applying a test voltage to the storage element after the formation of the conductive path;
determining an amount of current through the storage element based on the test voltage;
comparing the amount of current to a threshold or a threshold range; and
generating health data to indicate that the storage element has a particular status of multiple statuses based on the amount of read current being greater than or equal to the threshold or outside of the threshold range.

8. The method of claim 1, further comprising:
applying a test voltage to the storage element after formation of the conductive path;
determining an amount of leakage current associated with a neighboring storage element of the storage element based on the test voltage; and
storing the amount of leakage current as part of the data of the one or more parameters.

9. The method of claim 1, further comprising:
writing a data pattern to a region of the memory that includes the storage element after formation of the conductive path;
determining a bit-error-rate associated with the region based on the data pattern stored at the region; and
storing an indication of the bit-error-rate as part of the data of the one or more parameters.

10. The method of claim 1, further comprising:
applying voltage pulses to the storage element until detecting a transition of the storage element from a first resistance state to a second resistance state, the transition indicating formation of the conductive path;
determining a number of the voltage pulses applied to the storage element to form the conductive path;
comparing the number to a first threshold value or to a first threshold range; and
generating health data to indicate that the storage element has a particular status of multiple health statuses based on the number being greater than or equal to the first threshold value or being outside of the first threshold range.

11. The method of claim 1, further comprising:
applying voltage pulses to the storage element until detecting a transition of the storage element from a first resistance state to a second resistance state, the transition indicating formation of the conductive path;
determining an intensity value associated with the one or more voltage pulses applied to the storage element to form the conductive path;
comparing the intensity value to a second threshold value or to a second threshold range; and
generating health data to indicate that the storage element has a particular status of multiple health statuses based on the intensity value being greater than or equal to the second threshold value or being outside of the second threshold range.

12. The method of claim 11, wherein the intensity value is based on a total duration of the one or more voltage pulses applied to the storage element to form the conductive path, an amount of voltage applied to the storage element to form the conductive path, a number of the one or more voltage pulses applied to the storage element to form the conductive path, a total amount of power delivered to the storage element to form the conductive path, or a combination thereof.

13. The method of claim 1, further comprising generating health data to indicate that a neighboring storage element of the storage element has a particular status of multiple health statuses, wherein the health data is generated based on a number of voltage pulses of a set of one or more voltage pulses applied to the storage element to form the conductive path being less than or equal to a first threshold value, the number of voltage pulses being greater than or equal to a second threshold value, an intensity value associated with the set of one or more voltage pulses being less than or equal to a third threshold value, the intensity value being greater than or equal to a fourth threshold value, or a combination thereof.

14. The method of claim 1, further comprising initiating formation of a second conductive path through a second storage element of the resistance-based memory, wherein the second conductive path and the conductive path are formed in parallel, wherein the resistance-based memory is a resistive random access memory (ReRAM).

15. The method of claim 1, wherein the resistance-based memory includes a three-dimensional (3D) memory configuration that is monolithically formed in one or more physical levels of arrays of memory cells having an active area disposed above a silicon substrate, and wherein the resistance-based memory includes circuitry associated with operation of the memory cells.

16. A data storage device comprising:
a resistance-based memory, wherein the resistance-based memory stores reliability data associated with a characteristic of a conductive path of a storage element of the resistance-based memory; and
circuitry configured to perform a memory operation at a region of the resistance-based memory, wherein the region includes the storage element.

17. The data storage device of claim 16, wherein the characteristic corresponds to a resistance of the storage element that indicates successful formation of the conductive path, wherein the reliability data indicates the storage element has a particular status of multiple health statuses, and wherein the conductive path of the storage element corresponds to a filament of the storage element.

18. The data storage device of claim 16, wherein the characteristic is determined based on data collected during a formation stage associated with the conductive path.

19. A method comprising:
in a data storage device that includes a resistance-based memory, performing:
receiving a request to perform a memory operation;
responsive to the request, identifying a health indicator associated with a storage element of the resistance-based memory, wherein the health indicator is based on a characteristic of a conductive path associated with the storage element; and
performing the memory operation associated with the storage element, wherein a sub-operation of the memory operation is performed based on a value of the health indicator.

20. The method of claim 19, further comprising:
identifying a first value to be written to the storage element based on the memory operation, wherein the first value corresponds to a first resistive state of the storage element;
modifying the first value based on the value of the health indicator indicating that the storage element has a particular status of multiple health statuses to generate a second value that corresponds to a second resistive state of the storage element; and
programming the second value at the storage element.

21. The method of claim 19, further comprising:
detecting that the memory operation is associated with storing priority data at the resistance-based memory;
determining whether the value of the health indicator indicates that the storage element has a status of healthy; and
selecting the storage element to store the priority data responsive to a determination that the storage element has the status of healthy.

22. The method of claim 19, wherein the storage element is maintained as a reserved storage element based on the value of the health indicator indicating that the storage element has a particular status of multiple health statuses.

23. The method of claim 19, further comprising selecting the storage element to be used to perform the operation according to a wear-leveling technique, the wear-leveling technique directing one or more first storage elements having a first status to be selected prior to one or more second storage elements having a second status.

24. The method of claim 19, further comprising, when the memory operation includes a read operation:
performing the read operation at the storage element to read a data value from the storage element; and
providing a soft bit to a decoder of the data storage device responsive to the data value being read from the storage element, wherein the soft bit corresponds to the storage element, and wherein, when the health indicator indicates that the storage element has a status of faulty, the soft bit includes a value that indicates that the storage element is unreliable.

25. The method of claim 19, further comprising:
performing a read operation at a neighbor storage element of the storage element; and
providing a soft bit to a decoder of the data storage device responsive to the read operation, wherein the soft bit corresponds to the neighbor storage element, and wherein, when the health indicator indicates that the storage element has a status associated with being unhealthy or faulty, the soft bit includes a value that indicates that the neighbor storage element is unreliable.

26. The method of claim 19, wherein the memory operation includes a write operation, and further comprising:
identifying one or more regions of the memory that are available for the write operation;
identifying a set of health indicators that includes a corresponding health indicator for each of the one or more regions; and
identifying a particular health indicator as indicating a healthiest region of the one or more regions, wherein the memory operation is performed at the healthiest region.

27. A data storage device comprising:
a resistance-based memory including multiple storage elements; and
a controller coupled to the resistance-based memory, wherein the controller is configured to initiate a memory operation at a storage element of the multiple storage elements, the storage element selected based on a value of a health indicator associated with the storage element, and wherein the value of the health indicator is based on a characteristic of a conductive path associated with the storage element.

28. The data storage device of claim 27, wherein the memory operation is associated with one or more sub-operations, wherein the one or more sub-operations include a write operation, a read operation, a folding operation, a wear-leveling operation, an available region selection operation, a garbage-collection operation, or a combination thereof, and wherein the health indicator corresponds to a vertical bit line, a finger, a comb, a block, or a die that includes the storage element.

29. The data storage device of claim 27, further comprising a decoder configured to receive, from the controller, a soft bit corresponding to the storage element based on a read operation performed on the storage element, and wherein the soft bit indicates a reliability of the storage element determined based on the health indicator.

30. The data storage device of claim 27, further comprising read/write circuitry configured to modify, based on the health indicator, a write parameter associated with writing first data to the storage element or a read parameter associated with reading second data from the storage element.
